(19) United States
(12) Patent Application Publication
(10) Pub. No.: US 2025/0116697 A1
(43) Pub. Date: Apr. 10, 2025

(54) CURRENT PATH DIAGNOSIS WITH THE AID OF AN ELECTRONIC FUSE

(71) Applicant: HELLA GmbH & Co. KGaA, Lippstadt (DE)

(72) Inventors: Christopher LANKEIT, Paderborn (DE); Niklas MAY-JOHANN, Lippstadt (DE)

(73) Assignee: HELLA GmbH & Co. KGaA, Lippstadt (DE)

(21) Appl. No.: 18/907,489

(22) Filed: Oct. 5, 2024

(30) Foreign Application Priority Data
Oct. 5, 2023 (DE) 10 2023 127 066.4

(51) Int. Cl. G01R 31/28; G01R 31/327

(52) U.S. Cl. CPC G01R 31/2827; G01R 31/327

(57) ABSTRACT

A method for monitoring a circuit, in particular in order to make possible a predictive maintenance. At least one parameter is measured at least at one measurement position. The at least at one measurement position is located on or in the circuit. The at least one parameter is acquired. At least one actual value is calculated based on the at least one parameter. A deviation of the at least one actual value is determined from a target value. An analysis of the deviation is performed. An analysis result is output based on the analysis.

This nonprovisional application claims priority under 35 U.S.C. § 119(a) to German Patent Application No. 10 2023 127 066.4, which was filed in Germany on Oct. 5, 2023, and which is herein incorporated by reference.

### BACKGROUND OF THE INVENTION

### Field of the Invention

The invention relates to a method, a computing unit, a measuring device, a computer program product, a nonvolatile, computer-readable storage medium with the, as well as a vehicle.

### Description of the Background Art

Measuring devices for measuring parameters such as voltage or current are known. These devices can be used to characterize and/or to test circuits.

The known devices and methods from the prior art have various disadvantages, however. Thus, measurement tolerances are not taken into account in some cases, or if they are, then they are not adjusted. They may be unknown beforehand. Moreover, the measurements are not flexible in the arrangement of the measurement position and/or position of application within the framework of the measurement. Nor can any knowledge or empirical values be used, in particular in order to take change processes sufficiently into account. When components are used that have as yet been minimally tested or are entirely new, for example replacement parts that, in particular, may also come from third-party suppliers, sufficient adjustment of measurements and/or measurement tolerances cannot take place. Consequently, sufficiently good and/or reliable predictive maintenance cannot take place on the whole. In this context, it is not possible, in particular, to distinguish changed measurement tolerances from actual faults or aging processes. For example, a measurement offset, in particular resulting from a so-called ground shift, in particular a change in potentials or reference potentials, cannot be taken into account adequately or at all in this case.

### SUMMARY OF THE INVENTION

It is therefore an object of the present invention to at least partially overcome at least one of the above-described disadvantages. In particular, it is an object of the invention to reliably ascertain changes and/or aging processes over time. In this context, a distinguishing of or accounting for measurement tolerances and/or temperature changes that are variable, for example over time, can take place, in particular. Consequently, provision can be made to not only permit a more precise detection of failures or imminent faults, but also to prevent unnecessary repair, maintenance, and/or incorrect diagnoses.

Features and details that are described in connection with the method according to the invention also apply in connection with the computing unit according to the invention and/or in connection with the measuring device according to the invention and/or in connection with the computer program product according to the invention and/or in connection with the nonvolatile, computer-readable storage medium according to the invention and/or in connection with the vehicle according to the invention, and vice versa in each case, so mutual reference is and/or can always be made with regard to the disclosure of the individual aspects of the invention. In particular, advantages that are described within the scope of the first, second, third, fourth, fifth, and/or sixth aspect also apply in each case to the first, second, third, fourth, fifth, and/or sixth aspect.

Provided according to a first aspect of the invention is a method for monitoring a circuit, in particular in order to make possible a predictive maintenance, wherein the method includes at least one, preferably all, of the following steps: measuring at least one parameter at least at one measurement position, wherein the at least at one measurement position is located on or in the circuit; acquiring the at least one parameter; calculating at least one actual value based on the at least one parameter; determining a deviation of the at least one actual value from a target value; analysis of the deviation; and output of an analysis result based on the analysis.

In this context, the method can be used for monitoring the circuit, in particular the lines and/or electronic constituents, such as, e.g., a (switchable) electronic tripping unit or fuse. Especially preferably, measurement tolerances can be taken into account during measuring here. The method can accordingly be equipped to identify, to take into account, and/or to compensate for measurement tolerances that vary over time. In measurements of parameters, for example of current, voltage, and/or temperature, as well as particularly of a resistance, the measurement tolerance or an error in the measurement can vary over time and/or as a function of the parameters in this case. A simple example would be a changed temperature, which affects the resistance of a conductor, for example. This can be difficult to assess in advance, in particular for relatively complex circuits that have not yet been tested over a relatively long period of time (such as, e.g., months or years), for example. This can be especially serious in the case of newly developed circuits and/or components, for example. In this case, a predictive maintenance can advantageously be achieved in accordance with the invention, which, in particular, reduces costs and/or offers a saving of time. Moreover, downtime can be reduced. For example, it is possible that a circuit and/or a vehicle, e.g., an autonomous vehicle, undergoes maintenance and/or repair outside the time of use (e.g., at night) when an analysis of the deviation predictively makes this necessary and/or advisable. In addition, longer or continuous availability of the circuit can be ensured, which in particular saves costs and/or time. This can additionally reduce and/or prevent downtime, in particular at a point in time when the circuit and/or the vehicle is needed (e.g., during the day in the case of a taxi or bus). In addition, more robust and/or earlier fault response strategies can be made possible. Furthermore, long-term findings about the circuit, in particular about electronic tripping units (e.g., eFUSE), can be collected, evaluated, and/or used, for example in order to optimize the circuit and/or the electronic tripping unit. As a result, predictive maintenance can be provided that is even more precise.

The measuring in this case can include a detecting of a parameter. In the simplest case, current and/or voltage can be measured. The measuring can be accomplished by a measuring device and/or a computing unit here. Preferably, the monitoring of at least one or of all current paths as well as a current path diagnosis can therefore be accomplished. In this context, the measuring device can be connected to the computing unit by a data connection for data communication. The measuring device can transmit the at least one (measured) parameter to the computing unit in this case. The computing unit can control and/or regulate the measuring device through a data connection.

In this context, all steps can be carried out by a computing unit, in particular the measuring, acquiring, calculating, determining, analysis, and/or output. Alternatively or in addition, these steps can also be carried out by a (local) control unit, an additional (local) control unit (or control unit cluster), and/or an external computing cluster. In this context, an external computing cluster can include a cloud and/or high-performance computing unit that is connected to the circuit and/or computing unit through a data connection, for example. In this case, this can be carried out locally and/or in the external computing cluster depending on the complexity, for example. This can be made dependent on the necessary memory and/or the computing capacity.

The circuit can preferably be an electrical circuit whose constituents are electrically connected by lines.

The at least at one measurement position can be located on a line and/or on or in one of the devices, e.g., control unit(s). The at least at one measurement position, in particular all measurement positions, can be connected to the measuring device and/or the computing unit through a measurement connection in this case.

In this case the computing unit can be connected to the control unit, wherein the computing unit, in particular, is implemented separately from the control unit in order to advantageously permit easier maintenance or replacement, redundancy, and/or later integration into an existing system. Provision can also be made that the control unit includes the computing unit, wherein the computing unit constitutes an additional computing unit within the control unit, by which means a separate and/or more efficient calculation is advantageously made possible. In this case the control unit, the control units, and/or the computing unit can be connected to a power supply, in particular a battery.

The calculating, in particular by the computing unit, of at least one actual value based on the at least one parameter can use the at least one parameter as input in this case. Two or more parameters can also be used. For example, (measured) current and a (measured) voltage can be used, and an actual value, for example a resistance, can be calculated, in particular while taking into account a measured temperature (and/or additional measured parameters). Provision can additionally be made to take into account at least one of the following parameters: a line length; a line cross section; coefficients of line heating; and/or cable parameters (e.g., material, coefficient of thermal expansion, maximum temperature resistance).

The determining, in particular by the computing unit and/or an external computing cluster, can provide a deviation of the at least one actual value from a target value.

The acquiring here can include, in particular, a signal processing, for example an analog-to-digital conversion (ADC). The measured values, the converted values, the actual values, the target values, the measurement tolerances, the deviations, the analysis, and/or the analysis results can be stored in this case, for example on a nonvolatile, computer-readable storage medium that is connected to the computing unit, the control unit, and/or the measuring device.

In this context, the target value can represent a desired or expected value, in particular arising under specific circumstances, conditions, and/or (applied) parameters. For example, provision can be made that a target value of 5V should be measured at a current of 10 mA and 25° C. An actual value of 6V (under otherwise identical conditions) could indicate, e.g., an excessive voltage, wherein the deviation here is 1V, for example. However, this preferably can be made dependent upon whether the measurement tolerance here is less than 1V. If, for example, the measurement tolerance were to be 2V under corresponding conditions, it can be ascertained within the scope of the analysis that the deviation lies within the measurement tolerance, and thus no action (such as a maintenance) is necessary as an analysis result, in particular.

The circuit in this context can have a housing, in particular a one-piece or multipart housing, which at least partially encloses the circuit and advantageously protects it.

It can be advantageous within the scope of the invention that the circuit has at least one electronic tripping unit and/or at least one control unit, wherein the at least one parameter includes: a voltage and/or a current that, in particular, characterizes at least one current path of the electronic tripping unit; a voltage and/or a current of the at least one control unit, in particular at an output of the control unit; and/or a temperature at least at one measurement position of the circuit, in particular at the input and/or output of the electronic tripping unit.

In this case the circuit can have at least one electronic tripping unit (eFUSE). Especially preferably, the circuit has exactly one electronic tripping unit. This can provide adequate fuse protection and, in particular, can simultaneously permit implementation of the present method. Preferably, the at least at one measurement position is arranged near or at the at least one electronic tripping unit. In other words, the electronic tripping unit can be used here as an abstract current and/or voltage sensor for the measuring, by which means it can be used advantageously for both fuse protection and monitoring without requiring additional components.

Alternatively or in addition, additional parameters can be included, in particular temperature, (atmospheric) humidity, inclination, and/or speed (of motion). These can be measured through, e.g., corresponding sensors, preferably at measurement points.

In addition, at least one control unit can be provided that is connected to the electronic tripping unit. In this case, the electronic tripping unit can also be arranged within the control unit. Provision can be made that the electronic tripping unit protects the control unit, for example from overload such as voltage spikes and/or increased currents. Furthermore, at least one additional or multiple control units can be provided. At least two control units can form a control unit cluster here. In this case, multiple control units can be connected by corresponding lines. The at least at one measurement position can be arranged in, on, and/or between the control unit or the control units. Especially preferably, at least one measurement position is located near the electrical tripping unit in this case. Preferably, a measurement position in this case is arranged before, in particular directly before, and/or after, in particular directly after, the electronic tripping unit. In this way, the deviations can be detected especially efficiently. Alternatively or in addition, the at least at one measurement position can be located at, or in particular near, a terminal of the circuit, for example of the at least one control unit. This permits a measurement at any time and/or a compact design nevertheless. In addition, a line between the at least one control unit and additional components can therefore be acquired completely. Preferably, in this case the at least at one measurement position is arranged at an output channel or at all output channels of the at least one control unit and/or of all control units. In this way, fully comprehensive monitoring can be accomplished by multiple measurement positions. In addition or alternatively, it is possible that a measurement position is located at least at one supply input of the at least one control unit. A change can be acquired especially efficiently here because fluctuations can occur there that arise owing to, e.g., changing loading of the control unit.

Different switching states can be achieved through an automatic and/or forced switching of the electronic tripping unit. This can be used to carry out a measuring and/or the additional method steps in each case. Consequently, different information can be gathered in order to characterize the circuit and preferably to permit an analysis of a deviation.

The invention can permit an analysis of the current paths at an electronic tripping unit in this case, in particular despite (adversely) acting external influences such as, e.g., ground offsets and/or temperature dependence(s), which cause (variable) measurement tolerances, for example.

The at least one actual value can have an actual resistance and the target value has a target resistance, and/or wherein the analysis of the deviation is carried out based on the deviation and/or on a measurement tolerance, in particular a variable measurement tolerance.

For example, an actual or target parameter, in particular an actual or target resistance, can be calculated based on voltage and/or current. In the simplest case here, the resistance can be ascertained, at least in sections (relative to the line), through the quotients of voltage and current. Provision can also be made to calculate an estimate of the actual or target parameter based on one of these parameters and/or other parameters. Alternatively or in addition, additional parameters can be included, in particular temperature, pressure, action of force, (atmospheric) humidity, inclination, and/or speed (of motion). These can be measured, for example through corresponding sensors, preferably at measurement points. This makes possible a still more exact calculation of the actual value and/or target value.

Provision can be made in this case that the measuring of parameters is not exact, but instead is subject to a measurement tolerance, in particular a variable measurement tolerance (in particular measurement error), in particular inherently. Especially preferably, such a variable measurement tolerance is taken into account within the scope of the method. For example, the measurement tolerance can be dependent on the at least one parameter and/or applied parameters. A calculating of the (latest) measurement tolerance can preferably be accomplished as part of the calculation, preferably based on the at least one parameter. Especially preferably, all parameters ascertained in measuring (and acquiring) are taken into account.

Provision can be made within the scope of the invention that a learning method, in particular including at least one, preferably all, of the following steps, is carried out before the measuring, in particular upon startup: measuring the at least one parameter at least at one measurement position, wherein the at least at one measurement position is located on or in the circuit, acquiring the at least one parameter, calculating at least one actual value based on the at least one parameter, and/or defining the target value and/or a measurement tolerance based on the actual value.

An (initial) measurement tolerance based on the actual value and/or the target value can also be defined during the defining in this case. Especially preferably, the learning method is used in order to adjust the measurement tolerance. Furthermore, the target value can be defined based on the actual value and/or the measurement tolerance.

Preferably, a repeated performance of the learning method takes place here within the scope of the method. In this case, the learning method can be carried out proactively at the start, for example as part of installation. During (later) operation, the learning method can be used for readjustment.

The method and/or in particular the learning method can be computer-implemented in this case, for example by means of the (aforementioned units) computing unit, control unit, and/or external computing cluster. Moreover, an artificial intelligence can be employed here, in particular in order to make possible an improved pattern recognition, for example with respect to the shape and/or form of the envelope curve.

In this case, the measuring can be accomplished by a measuring device (see above) and/or a computing unit. Provision can be made that the remaining steps, in particular the acquiring, calculating, and/or defining, are carried out by the computing unit.

To start with, a learning method can be carried out in order to ascertain the characteristics of the respective lines, in particular in a vehicle. In this process, the at least one parameter can be determined at least at one measurement position, preferably at least at two measurement positions.

In this case an (initial and/or updated) measurement tolerance can be ascertained by repeated measuring. It is possible, for example, to proceed from the assumption that a circuit in which the individual components have passed all tests is functional. Repeated measuring under specific, preferably identical, conditions, such as, e.g., applied parameters, can then produce different results. The range of variation of these results can consequently yield the measurement tolerance for these very conditions. Provision can be made here to “run through” different conditions, in particular through different combinations of applied parameters, wherein the corresponding measurement tolerance, in particular, is defined in each case, for example initially. Provision can be made to adjust these, in particular individually or additionally in a readjustment period. Especially preferably, it is possible in this case to later ascertain more precisely and/or more reliably whether a deviation is due to actual changes in the circuit and/or a component, such as, e.g., a control unit, a line, and/or an electronic tripping unit, or whether, in particular, a deviation that purportedly is too large is instead due to a changed measurement tolerance. Especially preferably, the abovementioned advantages according to the invention can be realized as a result.

It is furthermore possible that the learning method includes an applying and/or, in particular subsequent, measuring of at least one of the following applied parameters: a voltage and/or a current that, in particular, characterizes at least one current path of the electronic tripping unit, a voltage and/or a current of the at least one control unit, in particular at an output of the control unit, and/or a temperature at least at one measurement position of the circuit, in particular at the input and/or output of the electronic tripping unit, wherein preferably at least one, preferably a multiplicity of, applied parameters are applied in and/or to the circuit, and a measuring is carried out, in particular subsequently and/or at the same time, in particular in order to ascertain a multiplicity of actual values and to obtain, based thereon, a multiplicity of (initial) target values and/or measurement tolerances.

In this case, provision can be made that the steps of the learning method, in particular with the same designation, correspond to a substantially identical procedure according to the method. For example, the measuring within the scope of the learning method can correspond to or be essentially identical to the (normal) measuring during operation.

Provision can be made in this case to measure and/or to apply a voltage between at least two measurement points.

In this case, the applied parameters can also include, in particular in addition to current, voltage, and/or temperature: application (or discontinuation) of action of force, in particular by impulses and/or periodic motions (e.g., vibration); application (or discontinuation) of reduced and/or increased air pressure (in particular in comparison with the atmosphere); application (or discontinuation) of, in particular repeated, rotation, inclination, and/or torsion; and/or removal of components from the circuit and/or connection of (additional) components.

In this process, an applied parameter can be applied to a measurement position (at which a measuring can also take place, in particular) or to a separate position of application, which advantageously is easier to reach and/or can be positioned in a cost-saving way (e.g., on a housing, in particular from outside). An applied parameter can be simulated by applying the parameter to a specific position of application. For example, an action of force can be applied near a support of the circuit in order to simulate a detachment of a fastening of the circuit. The effect on the parameters, in particular during measuring and the other above method steps, can subsequently be ascertained by the learning method. Consequently, an improved (predictive) maintenance and/or diagnosis is possible later, for example similar actions of force that give rise to corresponding measurement of actual values, but which now are due to an actual detachment of a fastening (with reference to the above example).

In this case, provision can be made that an (above-described) measuring, acquiring, calculating, and/or defining takes place upon an application, in particular every application, of a specific combination of parameters. In this way, a target value and/or a measurement tolerance can be ascertained in each case for different combinations of parameters. This can be advantageous, since it may potentially be possible to only partially apply this combination of parameters later, in particular during operation, for example because a part of the circuit is faulty or an application is not possible (e.g., the intentional discontinuation of impacts). Owing to the fact that a specific combination is not possible and/or a deviation between actual and target values is ascertained, maximally precise detection of faulty parts of the circuit can be made possible. As a result, these parts can be replaced in a targeted manner.

It is also possible that a spectrum analysis, comprising an applying of a multiplicity of frequencies, in particular for voltage and/or current, to at least one measurement position, is carried out in the learning method, wherein in particular the measuring, acquiring, calculating, and/or defining is carried out continuously in order to determine a multiplicity of (initial) target values and/or measurement tolerances that are used to create an initial envelope curve. In this case, the applying can alternatively or additionally include a measuring of current and/or voltage, wherein generated frequencies, for example ripple frequencies that are generated by the load, can be measured, in particular.

Especially preferably, the (initial) envelope curve is determined by target values and measurement tolerances in this process. In this case, a measurement tolerance can be assigned to each target value. A measurement tolerance in this case can preferably have a deviation or tolerance in at least one direction, preferably in both directions, wherein in particular one direction indicates toward larger values or smaller values. In this case it is possible, in particular, that the measurement tolerance is symmetrical (the same in both directions) or asymmetrical (different in the upward and downward directions). The precise determination of the measurement tolerance within the scope of the invention can make possible an especially reliable and/or precise analysis here.

In this context, an envelope curve can represent the shape of the target values and/or measurement tolerances, for example within the scope of an enveloping curve. For example, a target value can be represented, wherein the measurement tolerance surrounds the target value as an error bar or error cloud. In this case, the envelope curve can extend on both sides, in particular above and below the target values, in order to take into account an asymmetric distribution of the measurement tolerance, in particular. A one-dimensional or multidimensional concatenation of target values with corresponding measurement tolerances can then be surrounded by an envelope curve (or envelope cloud). The comparison between different envelope curves, preferably including essentially identical (applied) parameters, can then be used in order to carry out an analysis. Comparisons between actual and target values while taking into account measurement tolerances can preferably be carried out here. Alternatively or in addition, the form and/or the shape of the envelope curve preferably can also permit conclusions about the cause, which, in particular, would not otherwise be identifiable. For example, a particular fault, e.g., a short circuit or an interrupted line, can lead to very specific changes in the actual values, measurement tolerances, and/or, preferably, the envelope curve. For example, the envelope curve can additionally also be used to detect relatively small changes that, in particular, would not be detectable when only one actual and/or target value is used. For example, a gradual change, in particular one caused by a ground shift, particularly an increase in the resistance, can be detected better and/or more reliably through the use of the envelope curve.

Preferably, the applying as part of the spectrum analysis can be accomplished at least at two or at a multiplicity of measurement positions and/or positions of application. Especially preferably, at least one measurement position and/or position of application can be arranged between two components of the circuit in this case.

In this context, an envelope curve can have at least one, in particular initial, target value. When there are multiple parameters and/or multiple actual and/or target values, a readjustment of the target value or values and/or of the envelope curve can take place successively in this case.

Consequently, an envelope curve can be ascertained for the spectrum of the parameter change, in particular voltage changes, in the (initial) normal condition. A continuous spectrum analysis or a measurement of the (latest) envelope curve can then be carried out, in particular later within the framework of the method, in order to achieve a comparison and, in particular, to check functionality.

Deviations or faults can be reliably ascertained or predicted by means of the actual values, target values, measurement tolerances, and/or envelope curve, and preferably distinguished from incorrect detections or measurement tolerances.

The variation of the frequencies can serve here to detect a changed frequency response, for example on account of aging processes. Preferably, specific aging processes and/or failures can have a characteristic effect on the frequency response, and advantageously be ascertained within the scope of the spectrum analysis. A simple example would be the change in the frequency response in a coaxial cable when, e.g., a dielectric is damaged.

It is optionally possible within the scope of the invention that the learning method is continued for a readjustment period, in particular after an initial startup, preferably during operation of the circuit, in particular in order to take into account a change occurring over time in target values and/or measurement tolerances during measuring, and, based thereon, to adjust the target values, the measurement tolerances, and/or the initial envelope curve in order to obtain updated target values, updated measurement tolerances, and/or an updated envelope curve.

In this context, a readjustment period can comprise 12 months, in particular 6 months, preferably 4 months, especially preferably 3 months, ideally 2 months, advantageously 4 weeks.

In this context, a readjustment period can be defined at the factory.

In this context, a length of the readjustment period can be adjusted and/or increased. This can be ascertained via at least one characteristic of the actual value, the target value, the measurement tolerance, and/or the envelope curve. For example, a change (e.g., readjustment) that has not occurred, in particular with essentially identical (applied) parameters, in this case can indicate that a further adjustment is not necessary.

Preferably, deviations of the actual value from a target value outside of a corresponding measurement tolerance can be identified as a sign of aging and/or a failure, preferably after the conclusion of the readjustment period.

Within the scope of the invention, ‘a target value’ can also mean multiple target values if multiple actual values and/or parameters are used. In this context, each actual value or target value preferably can have a measurement tolerance.

Provision can be made in this case that the readjustment period and/or the learning method is at least partially restarted, in particular with regard to applicable parameters, when a replacement of a particular component has taken place. As a result, an especially good adjustment to a changed circuit can advantageously be accomplished in order to realize the advantages according to the invention.

A spectrum analysis preferably can be carried out repeatedly in the readjustment period.

Furthermore, provision can be made within the scope of the invention that the learning method is continued during operation of the circuit, in particular after an initial startup, by which means an updated target value, updated measurement tolerances, and/or an updated envelope curve, are ascertained, in particular continuously, wherein this takes place based on at least one of the following criteria: reception of at least one updated target value, updated measurement tolerance, and/or updated envelope curve, in particular through a data connection, and/or definition of an updated target value, updated measurement tolerance, and/or updated envelope curve, based on the reception and/or via user input.

In this case, the user input can be carried out by a driver and/or within the framework of a maintenance.

In this process, short-term, medium-term, and/or long-term deviations can advantageously be better identified and/or distinguished. In this context, provision can be made (as described above) to measure and/or apply the parameters again. On account of the performance of essentially identical measurements, it is possible in this way to determine how one or more measurement tolerances change.

In this case, provision can be made that a comparison from this point in time onward, particularly in the case of a readjustment, takes place with a readjusted target value and/or a readjusted envelope curve. This can be advantageous when, for example, specific measurement tolerances are changed later, e.g., in the case of aging. This can also be advantageous for the purpose of implementing an emergency operation program, wherein a deviation is initially identified, in particular outside the measurement tolerance, but a functionality of the circuit can be ensured at least temporarily, for example for the period until a repair shop is visited. In this case, provision can be made that a countermeasure, for instance an emergency stop and/or a more urgent warning, is issued [sic; should probably say “is taken”] if a new deviation is ascertained, in particular starting from a readjusted target value and/or a readjusted envelope curve.

In this case, provision can be made that the method, in particular the reception through the data connection, includes the receiving of information from another, preferably identically designed, circuit, by which means empirical values, in particular, can be employed from other circuits that have been used longer, differently, and/or more intensively, for example. In this case, the circuit can be connected to a data connection that transmits and/or receives corresponding data, for example through a LAN, WLAN, Bluetooth, cellular network, and/or Internet connection.

With respect to the present invention, it is possible that the determining of a deviation has at least one of the following steps: calculation of the difference between at least one actual value and a target value, in particular corresponding target value, and/or updated target value, and/or comparison between the initial envelope curve or updated envelope curve and the latest envelope curve, wherein, in particular, a difference is calculated between the initial envelope curve or updated envelope curve and the latest envelope curve.

In this context, a calculation of the difference of all actual values from corresponding target values can take place. Preferably, the magnitude of the difference is ascertained within the scope of the calculation, in particular in order to ascertain the absolute deviation. This can be critical for the urgency of an intervention, for example visiting a repair shop. In addition, the algebraic sign can also be ascertained, in particular in order to localize or ascertain the cause. For example, the absence of a voltage can indicate a break. In this way, a more precise determination of the source of the fault can be accomplished.

In this context, the latest envelope curve can be ascertained through measurement (as described above), in particular by the means that the essentially identical applied parameters are applied. The latest envelope curve can be determined, in particular, by a measuring during operation, for example within the framework of a check with the vehicle running. The difference in the envelope curves can be related to the individual actual values and corresponding target values. Alternatively or additionally, provision can also be made to consider the envelope curves or the envelope curve surfaces, and to ascertain differences between the surfaces. Specific deviations can be ascertained within the framework of pattern recognition, and in particular compared with historical data in order to permit, e.g., an improved determination of whether or not a deviation lies within a measurement tolerance, and/or to permit an improved determination of the cause.

Alternatively or in addition, the determining here can be carried out based on information from at least one other system, vehicle, and/or an entire vehicle fleet. This can be accomplished through, e.g., a data connection, in particular the Internet and/or a cloud. For example, actual values and/or target values can be provided in this way. A deviation can potentially be identified earlier and/or more reliably in this way. For example, a substantial change that experience shows has resulted in problems elsewhere can be detected earlier in this way, in particular as compared with a case in which no exchange occurs.

Furthermore, it is possible that the analysis ascertains whether a deviation lies within the measurement tolerance and/or updated measurement tolerance, and thus, in particular, is permissible or is impermissible, and/or that the analysis based on the deviation includes a determination of the cause of the deviation, and/or wherein, in particular, the output of the analysis result to a user takes place, wherein the analysis result includes a summary of the analysis, a classification of the analysis, and/or a recommended action.

The difference can be compared with the (updated) measurement tolerance in this case. If the difference lies within the measurement tolerance, or the measurement tolerance is larger, it can be concluded therefrom that the deviation is “reliable” or “normal,” in particular that it is not due to a fault and/or an aging process. If the difference is larger than the measurement tolerance, in particular at least 20% larger, for example 40% larger, preferably 60% larger, especially preferably 80% larger, it can be concluded therefrom that the deviation is “impermissible,” in particular that it is due to a fault, a failure, and/or an (excessive) aging process. In this case, a determination of the cause can show that a component is faulty, a short circuit is present, a break is present, a burned-out cable, and/or a defective (and possibly dangerous) electrical connection is present. This can be output, in particular as an analysis result.

In this context, the measurement tolerance and/or target values can be set at the factory, in particular initially. They can be adjusted within the framework of the learning process, in particular continuously, in particular in order to be able to take into account changes in the (applied) parameters such as, e.g., aging processes.

It can be especially preferred when the analysis includes a comparison of the deviation and/or measurement tolerance with a historical deviation and/or historical measurement tolerance. In this case, latest and/or historical (or past) deviations and/or measurement tolerances can be stored, for example on a nonvolatile, computer-readable storage medium, in particular of the computing unit, of the external computing cluster, and/or of the control unit. A time period can especially preferably be taken into account in this process, in particular a period over which the deviation and/or the measurement tolerances occur. In this case, the following categories can be distinguished: the deviation has a short-term deviation, in particular this short-term deviation is due to temporarily limited influences, such as, e.g., an especially high temperature at least at one measurement position. An example would be a short-term deviation with extremely high outdoor temperatures of, e.g., 48° C. In this context, a short-term deviation can comprise the past 48 hours, in particular the past 24 hours, preferably the past hour, especially preferably the past minute, ideally the past 20 seconds; the deviation has a medium-term deviation, in particular this medium-term deviation is due to temporarily limited, but repeated, influences, such as, e.g., a comparatively high temperature at least at one measurement position. A simple example in this case can be a vacation trip to an especially hot place with a prevailing average temperature of 45° C., for instance. In this context, a medium-term deviation can comprise the past 4 months, in particular the past 2 months, preferably the past month, especially preferably the past 3 weeks, ideally the past 2 weeks, advantageously the past week; and/or the deviation has a long-term deviation, in particular this long-term deviation is due to influences that are not temporarily limited, such as, e.g., a geometric deformation of at least a part of the circuit, an at least partial oxidation, an electrical break, and/or a short circuit. In this context, a long-term deviation can comprise the past 36 months, in particular the past 24 months, preferably the past 12 months, especially preferably the past 6 months, ideally the past 4 months, advantageously the past 2 months.

Depending on the category, preferably the output result can include the category, a recommended action, and/or a fault diagnosis, wherein the output result preferably is output acoustically and/or visually.

Especially preferably, short-term and/or medium-term deviations can be calculated locally in this case, in particular by the computing unit, the control unit, and/or the measuring device. Especially preferably, medium-term and/or long-term deviations can be calculated externally in this case, in particular by the external computing cluster. In this way, a simpler and/or more data-efficient provision of the data for others and a simpler and/or more data-efficient consideration of other information (e.g., from other circuits of identical design) can be accomplished.

In this context, provision can be made to ascertain deviations, for example deviations in terms of absolute magnitude, in the actual parameter from the target parameter of 0.0001 to 10000%, in particular of 0.001 to 1000%, preferably of 0.01 to 100%, especially preferably of 0.1 to 10%. For example, a deviation of at least 10 ohm, in particular of 1 ohm, preferably of 0.1 ohm, especially preferably of 0.01 ohm, ideally of up to 0.004 ohm, can preferably be ascertained. In this way, even small deviations in comparatively complex circuits, such as in vehicles, for example, can be ascertained.

It is furthermore possible that the user is prompted, for example through a display that advantageously is also used for output, to comment on changed parameters. For example, an elevated temperature persisting for several days could indicate a vacation trip in an especially hot country. If reasonable doubts concerning the analysis should exist, however, then certain faults can be ruled out in this way. The user can enter corresponding (prevailing) parameters in this way, for example through an input device. Incorrect diagnoses can be prevented as a result.

In this context, a recommended action can include stopping soon, stopping immediately, and/or visiting a repair shop. A user, in particular a driver, can be warned in this manner.

In this case, a fault diagnosis can include the specific explanation for the reason of the deviation, for example a failure of the electronic tripping unit, of the control unit, and/or of a line. For example, a current flow that cannot be measured at the input of a component, in particular repeatedly, can mean a break. As a result, an improved maintenance and/or simplified troubleshooting can be made possible, by which means costs and/or materials can advantageously be saved.

The output result can be output acoustically in this case, for example through a speaker, headphones, and/or a mobile device such as a cellular telephone and/or a watch. Alternatively or in addition, the output result can be output visually, for example (in particular in a vehicle) through a screen, a head-up display, an operator console, a screen of a mobile device such as, e.g., a cellular telephone and/or a watch.

Alternatively or in addition, an outputting in this context can also include transmitting over a data connection. In this way, the deviation and/or the analysis result can also be made available to other circuits, computing units, control units, and/or vehicles. This can make it possible to also use corresponding external information and/or to compile statistics regarding breakdowns, failures, repairs, maintenance, aging processes, classification, and/or recommended actions. As a result, an even more precise predictive maintenance can be provided. The downtime can also be minimized in this way.

The aforementioned object is furthermore attained according to a second aspect by a computing unit according to the invention comprising electronics for carrying out the method.

The aforementioned object is furthermore attained according to a third aspect by a measuring device for measuring a control of a circuit, wherein the measuring device is equipped to carry out an essentially synchronous measurement of the at least one parameter, and in particular to implement the method according to the first aspect.

Provision can be made in this case that the measuring device is equipped to measure at least two, preferably a multiplicity of, parameters.

In this context, the measuring device can have a computing unit, in particular a computing unit according to the invention. This permits an especially compact and/or economical design.

Also, a device can be provided, in particular comprising a circuit that is equipped to implement the method according to the first aspect.

The aforementioned object is furthermore attained according to a fourth aspect by a computer program product according to the invention comprising instructions that can be executed by a computing unit and that, upon execution of the program by a computing unit, cause the computing unit to implement the method according to the first aspect.

The aforementioned object is furthermore attained according to a fifth aspect by a nonvolatile, computer-readable storage medium according to the invention that includes a computer program product according to the fourth aspect.

The aforementioned object is furthermore attained by a vehicle according to the invention that includes at least one nonvolatile, computer-readable storage medium according to the fifth aspect.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a circuit according to an example of the invention;

FIG. 2 shows a method according to an example of the invention;

FIG. 3 shows a method according to an example of the invention;

FIG. 4 shows method according to an example of the invention;

FIG. 5 shows a learning method according to an example of the invention;

FIG. 6 shows a learning method according to an example of the invention; and

FIG. 7 shows a method according to an example of the invention.

### DETAILED DESCRIPTION

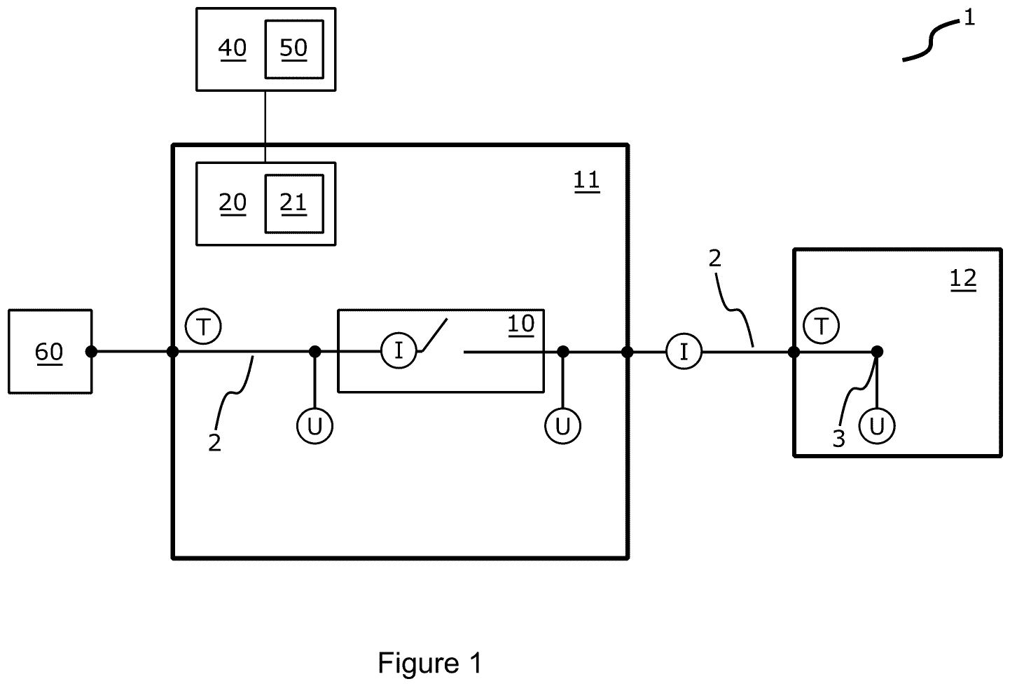

FIG. 1 shows a circuit 1 that has a control unit 11 and, in the present case, an additional control unit 12. Together these can form a control unit cluster. The circuit can have a power supply 60, for example a battery 60. The constituents of the circuit 1 can be connected by lines 2. The control unit 11 has a computing unit 20 comprising a processor and/or memory 21 that are designed, in particular, to carry out the method 100. In addition, the computing unit 20 can be connected to a storage medium 40, or can have the same. The storage medium includes a computer program 50. Parameters such as voltage U, current I, and/or temperature T can be applied and/or measured at one or more measurement positions 3. In this context, the circuit 1 or the control unit 11 can have an electronic tripping unit 10.

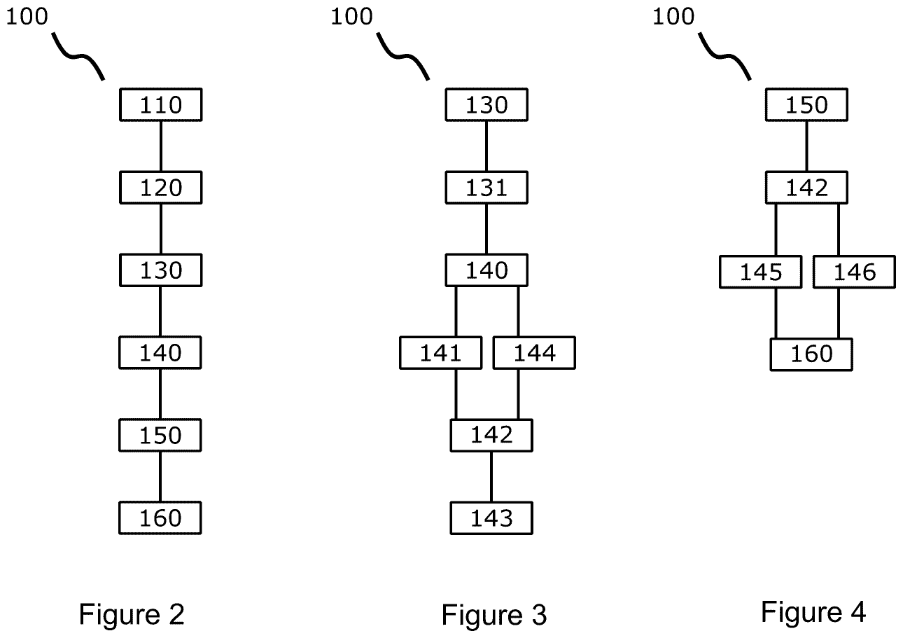

FIG. 2 shows, by way of example, a method 100 comprising the steps: measuring 110 at least one parameter I, U, T; acquiring 120 the parameter; calculating 130 an actual value; determining 140 a deviation; analysis 150 of the deviation; and an output 160 of an analysis result.

FIG. 3 shows, by way of example, additional details of the method 100, wherein the calculating 130 of an actual value based on the at least one parameter I, U, T takes place. In this context, a resistance, for example, can be calculated from current and voltage while taking into account the temperature, for example. The determining 140 of a deviation 142 of the at least one actual value from a target value 141 or updated target value 144 can additionally be carried out in order to obtain a deviation 142, which can stem from a difference 143 between target value and actual value, for example.

FIG. 4 shows, by way of example, additional details of the method 100, wherein the analysis 150 can be based on the deviation 142. In addition, the (initial) measurement tolerance 145 and/or updated measurement tolerance 146 can also be taken into account here. An output of an analysis result 160 can take place in the last step.

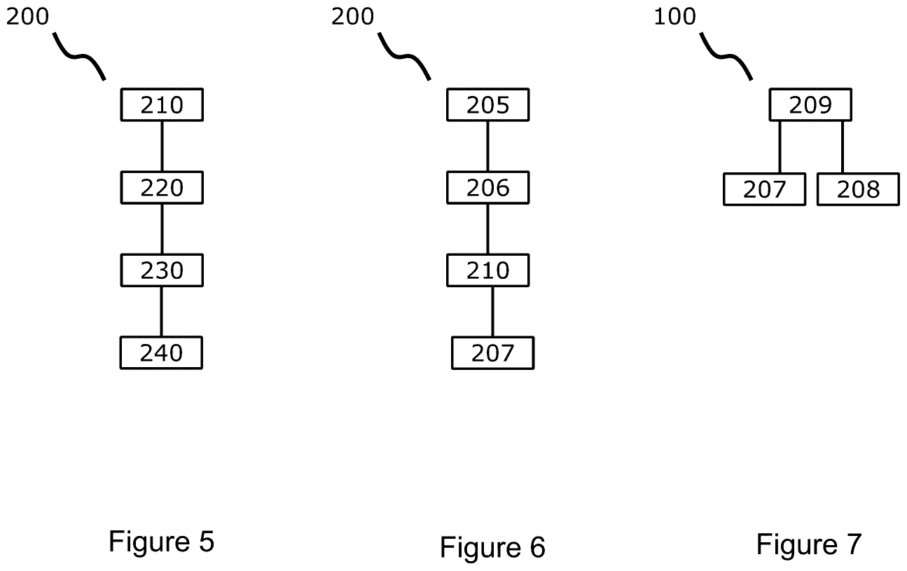

FIG. 5 shows, by way of example, a learning method 200 comprising the steps: measuring 210 the at least one parameter (I, U, T); acquiring 220 the at least one parameter (I, U, T); calculating 230 at least one actual value; and defining 240 the target value and/or a measurement tolerance.

FIG. 6 shows, by way of example, a learning method 200 comprising an application of applied parameters I, U, T. A spectrum analysis 206 can be carried out in this process. This analysis can be carried out repeatedly, in particular within a readjustment period that can be used for adjusting target values and/or measurement tolerances.

FIG. 7 shows, by way of example, a method 100 in which a latest envelope curve 209 is compared with an initial envelope curve 207 and/or an updated envelope curve 208. Preferably, the initial envelope curve 207 is readjusted within the framework of a learning method 200, which in particular can take place beforehand as part of the method 100, in order to obtain an updated envelope curve. In this way, target values, the envelope curve, and/or measurement tolerances can be readjusted.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for monitoring a circuit to provide a predictive maintenance, the method comprising:
measuring at least one parameter at least at one measurement position, the at least at one measurement position being on or in the circuit;
acquiring the at least one parameter;
calculating at least one actual value based on the at least one parameter;
determining a deviation of the at least one actual value from a target value;
analyzing the deviation; and
outputting an analysis result based on the analysis.

2. The method according to claim 1, wherein the circuit has at least one electronic tripping unit and/or at least one control unit, wherein the at least one parameter comprises:
a voltage and/or a current that characterizes at least one current path of the electronic tripping unit;
a voltage and/or a current of the at least one control unit at an output of the control unit; and/or
a temperature at least at one measurement position of the circuit at an input and/or output of the electronic tripping unit.

3. The method according to claim 1, wherein the at least one actual value has an actual resistance and the target value has a target resistance, and/or wherein the analysis of the deviation is carried out based on the deviation and/or on a measurement tolerance or a variable measurement tolerance.

4. The method according to claim 1, wherein a learning method including at least one of the following steps is carried out before the measuring or upon startup:
measuring the at least one parameter at the at least one measurement position, the at least at one measurement position being located on or in the circuit;
acquiring the at least one parameter;
calculating at least one actual value based on the at least one parameter; and/or
defining the target value and/or a measurement tolerance based on the actual value.

5. The method according to claim 4, wherein the learning method includes an applying and/or subsequent measuring of at least one of the following applied parameters:
a voltage and/or a current that characterizes at least one current path of the electronic tripping unit;
a voltage and/or a current of the at least one control unit at an output of the control unit; or
a temperature at at least at one measurement position of the circuit at the input and/or output of the electronic tripping unit,
wherein at least one or a plurality of applied parameters are applied in and/or to the circuit, and
wherein a measuring is carried out subsequently and/or essentially at the same time in order to ascertain a plurality of actual values and to obtain, based thereon, a plurality of target values and/or measurement tolerances.

6. The method according to claim 4, wherein a spectrum analysis comprising an applying of a plurality of frequencies for voltage and/or current to at least one measurement position is carried out in a learning method, wherein the measuring, acquiring, calculating, and/or defining is carried out continuously in order to determine a plurality of target values and/or measurement tolerances that are used to create an initial envelope curve.

7. The method according to claim 4, wherein the learning method is continued for a readjustment period, after an initial startup, during operation of the circuit in order to take into account a change occurring over time in target values and/or measurement tolerances during measuring, and, based thereon, to adjust the target values, the measurement tolerances, and/or an initial envelope curve in order to obtain updated target values, updated measurement tolerances, and/or an updated envelope curve.

8. The method according to claim 4, wherein the learning method is continued during operation of the circuit after an initial startup, via which updated target values, updated measurement tolerances, and/or an updated envelope curve are ascertained continuously, and wherein this takes place based on at least one of the following criteria:
reception of at least one updated target value, updated measurement tolerance, and/or updated envelope curve through a data connection; or
definition of an updated target value, updated measurement tolerance, and/or updated envelope curve based on the reception and/or via a user input.

9. The method according to claim 1, wherein the determining of a deviation comprises:
calculating a difference between at least one actual value and a target value and/or updated target value; and
comparing between the initial envelope curve or updated envelope curve and a latest envelope curve,
wherein the difference is calculated between the initial envelope curve or updated envelope curve and the latest envelope curve.

10. The method according to claim 1, wherein the analysis ascertains whether a deviation lies within the measurement tolerance and/or updated measurement tolerance and is permissible or is impermissible, and/or wherein the analysis based on the deviation includes a determination of the cause of the deviation, and/or wherein the output of the analysis result to a user takes place, wherein the analysis result includes a summary of the analysis, a classification of the analysis, and/or a recommended action.

11. A computing unit comprising a processor for carrying out the method according to claim 1.

12. A measuring device to measure a control of a circuit, wherein the measuring device is configured to carry out an essentially synchronous measurement of the at least one parameter and to implement the method according to claim 1.

13. A computer program product comprising instructions that are adapted to be executed by a computing unit and, upon execution of the program by a computing unit, cause the computing unit to implement the method according to claim 1.

14. A nonvolatile, computer-readable storage medium comprising a computer program product according to claim 13.

15. A vehicle comprising at least one nonvolatile, computer-readable storage medium according to claim 14.
